(19) United States
(12) Patent Application Publication
(10) Pub. No.: US 2007/0260955 A1
(43) Pub. Date: Nov. 8, 2007

(54) TEST AUXILIARY DEVICE IN A MEMORY MODULE

(76) Inventors: Joerg Kliewer, Munich (DE); Manfred Proell, Dorfen (DE); Stephan Schroeder, Munich (DE); Georg Eggers, Munich (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/677,572

(22) Filed: Feb. 21, 2007

(30) Foreign Application Priority Data
Feb. 21, 2006 (DE) 102006007993.0-55

(51) Int. Cl. G01R 31/28

(52) U.S. Cl. 714/734

(57) ABSTRACT

Methods and apparatus for applying a test pattern to cells in a memory module. A test auxiliary device in a memory module contains a test pattern selection device for selecting a test pattern from at least two elementary M-bit test patterns. The test pattern is applied to a group of M data lines of the memory module, M being an integer.

### CROSS-REFERENCE TO RELATED APPLICATIONS

This application claims foreign priority benefits under 35 U.S.C. §119 to co-pending German patent application number DE 10 2006 007 993.0-55, filed 21 Feb. 2006. This related patent application is herein incorporated by reference in its entirety.

### BACKGROUND OF THE INVENTION

1. Field of the Invention

The invention generally relates to testing and more particularly to testing memory modules.

2. Description of the Related Art

In order to check the functionality of a memory module, various tests are needed at various stages in production and even after completion. Such tests involve, in principle, writing a respective particular item of data to each memory cell and checking, during subsequent read accesses, whether the data which have been read out match the data which were previously written in. Memory tests are usually carried out with the aid of external test devices which operate in accordance with a selectable test program in order to provide the respective address and data information for the selection of the memory cells and for the data to be written in, and also to provide command bits for prescribing the respective operating mode of the memory module and to generate strobe signals for interrogating the test results.

However, current testing techniques have various disadvantages. For example, conventional testing typically involves writing a given pattern (e.g., 4 bit pattern) repetitively to a memory area. This repetitive pattern is not realistic and, hence, incapable of exposing certain memory defects. For example, current testing schemes cannot test for crosstalk between lines.

Therefore, a method and apparatus for testing memory devices is needed.

### SUMMARY OF THE INVENTION

Embodiments of the invention generally provide for methods and apparatus for testing memory devices.

In one embodiment, a test auxiliary device in a memory module contains a test pattern selection device for selecting a test pattern from at least two elementary M-bit test patterns. The test pattern is applied to a group of M data lines of the memory module, M being an integer. Different test patterns from different test sources can be interleaved to form different test bit combinations.

### BRIEF DESCRIPTION OF THE DRAWINGS

The features of the embodiments of the present invention will become clear from the following description, taking in conjunction with the accompanying drawings. It is to be noted, however, that the accompanying drawings illustrate only typical embodiments of the present invention and are, therefore, not to be considered limiting of the scope of the invention. The present invention may admit other equally effective embodiments.

FIG. 1 shows a schematic fragmentary illustration of a memory module having a test auxiliary device which operates according to a compressed test mode (ACTM).

FIG. 2 shows the division, which is possible with the known test auxiliary device, of 4-bit test data patterns between the N=64 lines of the internal data line bus of the memory module.

FIG. 3 shows a memory module with a test auxiliary device according to a first embodiment of the invention.

FIG. 4 shows two examples of the division, which is possible with the test auxiliary device shown in FIG. 3, of 4-bit test data patterns between the N=64 lines of the internal data line bus.

FIG. 5 shows a memory module with a test auxiliary device according to a second embodiment of the invention.

FIG. 6 shows two examples of the division, which is possible with the test auxiliary device shown in FIG. 5, of 4-bit test data patterns between the N=64 lines of the internal data line bus.

### DETAILED DESCRIPTION OF THE PREFERRED EMBODIMENT

In the Figures, identical or similar elements (circuit parts and signals) are denoted using the same combinations of letters, each of which has a number placed after it in order to identify the element in question, the number “i” being representative of any desired number. A colon between two numbers signifies the word “to”; for example “bits A0:3” should thus be read as “bits A0 to A3”. In the description below, the digits “0” and “1” in quotation marks are used to denote binary states (logic values). In the figures of the drawing, these binary digits are respectively written in bold.

The maximum possible data throughput of memory modules, that is to say the maximum number of data bits read or written per unit time, is primarily determined by four factors. The first factor is the “latency” T which elapses from the beginning of the operation of addressing a memory cell until a supplied data bit is effectively written to the cell or until the data bit stored in the cell is effectively read. The second factor is the “internal parallelism”, that is to say the number N of memory cells which can be simultaneously addressed and operated in order to simultaneously read or write a correspondingly large number of data bits from or to all of these cells. The third factor is the “external parallelism”, that is to say the number Q of external parallel data connections at which a corresponding number of data bits can be respectively input and output in the form of a parallel data word. The fourth factor is the “external data rate” f_{Q}, that is to say the repetition frequency of the parallel words which are input and output via the external data connections.

The latency T is determined, inter alia, by the charging and discharging time constants of the memory cells and by the response times of the read/write amplifiers in the memory cells. The reciprocal value 1/T determines the maximum possible access frequency, that is to say the maximum magnitude of the repetition frequency f_{N} of successive read or write accesses to the cell array of the memory module. Even with advanced memory technology, it is possible to shorten the latency only to an insignificant extent. Therefore, in order to enable a high data throughput, all efforts are aimed at making the internal parallelism N as high as possible. On the other hand, an attempt is made to keep the number of external connections in a memory module small, but this restricts the external parallelism Q.

Therefore, a mode in which the internal parallelism N is an integer multiple P of the external parallelism Q and in which the external data rate f_{Q} is a corresponding multiple P of the access frequency f_{N} is chosen for modern memory modules. That is to say the N data bits for a respective memory access (that is to say to read or write N data bits from or to N addressed memory cells in a parallel manner) are passed, in the form of a burst of P successive Q-bit data words, using the Q data connections of the memory module, to be precise at a repetition frequency (external data rate) of f_{Q}=P*f_{N} (the symbol * is the multiplication operator in this case and in the text below). Operating modes with P=2 (double data rate, abbreviated to “DDR”) or P=4 (“DDR2 mode”) or P=8 (“DDR3 mode”) are currently customary. Q=4 (“x4 configuration”), Q=8 (“x8 configuration”) and Q=16 (“x16 configuration”) are customary for external parallelism. N=16, N=32, N=64 and N=128 are customary for internal parallelism. Development is heading in the direction of further increasing the internal parallelism N, in particular whilst increasing the number P.

If N is a multiple P of Q, all P*Q data bits of an applied data burst must be respectively collected in an interface within the memory module and provided in the form of N parallel data bits for each write access. This operation is also referred to as “prefetch”. The N parallel bits are then passed, via an internal bus comprising N parallel data lines, to an address-controlled switching device which establishes the connection to N addressed memory cells. In the read mode, the switching device passes the N data bits, which were simultaneously read from N addressed memory cells for each read access, to the internal N-bit parallel bus. In the interface, the N parallel bits which have been read are converted into a burst comprising P successive Q-bit data words which are output at the data rate f_{Q}=P*f_{N} using the Q data connections.

In order to check the functionality of a memory module, various tests are needed at various stages in production and even after completion. Such tests involve, in principle, writing a respective particular item of data to each memory cell and checking, during subsequent read accesses, whether the data which have been read out match the data which were previously written in. Memory tests are usually carried out with the aid of external test devices which operate in accordance with a selectable test program in order to provide the respective address and data information for the selection of the memory cells and for the data to be written in, and also to provide command bits for prescribing the respective operating mode of the memory module and to generate strobe signals for interrogating the test results.

Ever larger storage densities result in ever longer test times for each memory module. Since the test time is an important cost factor, an attempt is made to shorten it. A “compressed test mode”, which is also known by the abbreviation ACTM (Advanced Compression Test Mode), is a contribution to shortening the test time which has become customary in the meantime. In this test mode, an elementary test data pattern is used for each write access to N memory cells, said test data pattern comprising only 4 bits even if N is a multiple of 4. The number 4 is used for reasons of the special cell topology of conventional memory modules. In this topology, the memory cells are arranged in rows and columns in the form of a matrix, and 4 memory cells which are beside one another in a matrix row and form a so-called “quadruple” are respectively selected using a common column address. A quadruple is thus the smallest selectable subset of memory cells. In this case, the number N must of course be an integer multiple of 4. During write access in the ACTM, the elementary 4-bit test data pattern is thus applied to each bundle of 4 respective data lines (line quadruple) of the internal N-bit data bus, with the result that the same 4-bit pattern is written to all addressed cell quadruples.

The ACTM test method is somewhat lacking in terms of the meaningfulness of the functionality of the memory module in the actual useful mode.

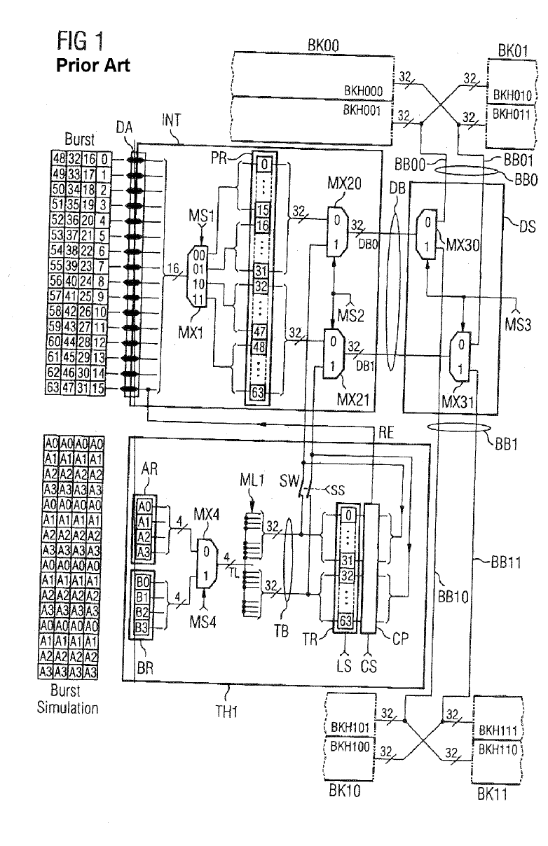

The memory module shown in FIG. 1 is an example of a DRAM module, all of the circuit parts of which are integrated on a semiconductor chip. The module has a multiplicity of external connections, only the row of Q data connections (data pins) DA of which is illustrated, at which the memory data are respectively input and output in the form of Q-bit words in a parallel manner. In the example shown, the number Q of data connections (that is to say the “external parallelism” of the module) is equal to 16.

The memory cells which are arranged in rows and columns in the form of a matrix are accommodated in four quadrants which form the so-called “banks” which are denoted BK in this case and are numbered using a two-digit binary number 00, 01, 10, 11. For its part, each bank is divided into two bank halves which are denoted BKH in this case and are numbered using a three-digit binary number, the first two digits of which are the number of the bank in question and the third digit of which, 0 or 1, identifies the “first” or “second” bank half. Each bank BKi has a multiplicity of N local data connections, N/2 in each bank half, in order to be able to simultaneously read or write N data bits from or to N addressed memory cells in the bank. In the case shown, the number N (that is to say the “internal parallelism” of the module) is equal to 64.

In order to read or write a packet of N=64 data bits from or to a bank in a parallel manner, the bank in question and 16 respective memory cell quadruples are addressed, this addressing selecting 8 quadruples (that is to say 32 cells each) in each of the two bank halves. The address information, which is applied to external address connections (not shown) of the memory module and is decoded inside the memory module, is used to establish data transmission paths between 32 chosen cells and 32 data connections of each of the two banks halves using a switchable network of row and column selection lines within the bank.

In the write mode, the N data bits to be written are applied to the Q external data connections DA in successive packet elements or “words” of Q respective parallel bits. With N=64 and Q=16, P=N/Q=4 successive 16-bit words are required for this purpose. This “data burst” comprising 4 successive 16-bit words is illustrated on the left-hand side of FIG. 1 beside the data connections DA in the form of a 4×16 matrix in which the total of 64 bits are numbered using numbers 0:63. Each column of this matrix contains the numbers of 16 respective bits which form one of the four 16-bit parallel words. Accordingly, the first word of the burst comprises the bits #0:15, the second word comprises the bits #16:31, the third word comprises the bits #32:47 and the fourth word comprises the bits #48:63.

The 4×16 data burst received is converted, in a data interface INT of the memory module, into the 64-bit parallel word in order to be forwarded to the 64 data connections of the addressed bank. As shown in the illustration in FIG. 1, this can be carried out using a four-way changeover switch MX1 and a 64-bit prefetch register PR. The changeover switch MX1 has a 16-bit main connection which is connected to the 16 external data connections DA and can be changed over between four switching states “00”, “01”, “10”, “11” using a 2-bit control signal MS1 in order to selectively connect the main connection to one of four 16-bit branch connections. Each of these branch connections leads to an associated group of 16 respective register cells in the 64-bit prefetch register PR.

The four 16-bit words in the received data burst, which arrive at the main connection of the changeover switch MS1 at a repetition frequency f_{Q}, are successively distributed among the four 16-bit cell groups of the prefetch register PR by gradually changing over this changeover switch in synchronism with the frequency f_{Q} and are buffer-stored in said register in the form of a 64-bit data word. As soon as this data word in the register PR is complete, that is to say after four periods of the frequency f_{Q}, all 64 bits are read from the register PR in a parallel manner and are transmitted to the 64 lines of an internal 64-bit data bus DB.

In the case shown, the data bus DB is divided into two halves DB0 and DB1 each with 32 lines, the first bus half DB0 being able to be selectively connected to the prefetch register cells for the data bits #0:31 or to a test auxiliary device TH1, which is described further below, using a two-way changeover switch MX20. the second half DB1 of the bus DB can be selectively connected to the prefetch register cells for the data bits #32:63 or to the test auxiliary device TH1 using a two-way changeover switch MX21. In the normal useful mode of the memory module, the changeover switches MX20 and MX21 are set by the binary value “0” of a control signal MS2 in such a manner that the bus halves DB0 and DB1 are connected to the associated cells of the prefetch register PR.

In order to transmit the 64 data bits from the data bus DB to the 64 data connections of the respective addressed bank, provision is made of a data path switching device DS which, in the case shown, is implemented using two two-way changeover switches MX30 and MX31 which can be controlled using a bank pair selection bit MS3. This selection bit MS3 is part of the address information. If MS3=“0”, the changeover switches MX0, MX1 connect the halves DB0 and DB1 of the data bus DB to correspondingly broad halves BB00, BB01 of a bank bus BB0 which leads to the bank pair BK00, BK01. If MS3=“1”, the changeover switches MX30, MX31 connect the bus halves DB0 and DB1 to correspondingly broad halves BB10, BB11 of a bank bus BB1 which leads to the bank pair BK10, BK11.

In the case shown, BB00 is connected both to the 32 data connections of the second half BKH001 of the first bank BK00 and to the 32 data connections of the first half BKH010 of the second bank BK01, and BB01 is connected both to the 32 data connections of the first half BKH000 of the first bank BK00 and to the 32 data connections of the second half BKH011 of the second bank BK01. To this end, the lines of the two bank bus halves BB00 and BB01 must cross over (preferably in the center and at the average height between the banks BK00 and BK01). In a similar manner, BB10 is connected both to the 32 data connections of the second half BKH101 of the third bank BK10 and to the 32 data connections of the first half BKH110 of the fourth bank BK11, and BB1 is connected both to the 32 data connections of the first half BKH100 of the third bank BK10 and to the 32 data connections of the second half BKH111 of the fourth bank BK11, in which case it is necessary for the bank bus halves BB10 and BB11 to cross over in this case too.

In this manner, two banks of a bank pair BK00, BK01 or BK10, BK11 respectively share a common bank bus BB0 or BB1 for N parallel bits, with the result that the space between the two banks in a pair does not need to be larger than the space required for N parallel bus lines. The externally applied bank address determines that bank in a bank pair which is intended to be subjected to a write access (or read access) using the data bits which are carried via the common data bus.

In the normal read mode of the memory module, data are transmitted in the opposite direction. The data bits which are read in a parallel manner from the N=64 addressed memory cells in the respective addressed bank are passed to the prefetch register PR via the data connections of the bank in question, the associated bank bus and the data bus DB. The 64 cells in the prefetch register PR are then successively read in four successive groups of 16 respective parallel bits using the changeover switch MX1, with the result that a burst of 4 successive 16-bit data words appears at the 16 data connections.

In order to test the memory module shown in FIG. 1, the control signal MS2 is set to “1”, with the result that the internal data bus DB is connected to the test auxiliary device TH1. This device TH1 contains two bit pattern sources AR and BR, each of which provides a pattern of 4 parallel test data bits A0:3 and B0:3 which are respectively intended to be written to a memory cell quadruple of the memory module. A two-way changeover switch MX4 can be changed over using a binary control signal MS4 in order to pass either the test data bits A0:3 or the test data bits B0:3 to a four-core line bundle TL in selected fashion. In a branching device ML1, this bundle TL is branched or fanned out into 16 four-core bundles in such a manner that each of these 16 branch bundles provides the 4 selected test data bits A0:3 or B0:3. A test data word comprising 64 parallel bits thus results on 64 parallel lines.

In the test write mode, the 64 test data bits from the branching device ML1 are held (“latched”) in a 64-bit test word register TR in response to a latch command LS. At the same time, a 64-pole line switch SW is closed by activating a switching signal SS, with the result that the 64-bit test data word is passed to the 64-bit data bus DB via the multiplexers MX20, MX21. This test data word is written to 64 addressed memory cells in an addressed bank, to be more precise to 16 addressed cell quadruples of the bank, in the same manner in which the 64-bit word buffer-stored in the prefetch register PR is written in the normal write mode. The test data word from the test auxiliary device thus simulates an input data burst comprising P=4 successive identical 16-bit data words, each of which comprises four identical 4-bit patterns. The bit pattern of this “simulated” data burst is illustrated on the left-hand side of FIG. 1 for the case in which the changeover switch MX4 selects the test data bits A0:3.

In the test read mode, the line switch SW is opened, with the result that the data bits read from the 64 addressed memory cells can now appear on the data bus DB in order to be passed, via the changeover switches MX20, MX21, to a first 64-bit input of a comparison device CP within the test auxiliary device TH1. A second 64-bit input of the comparison device CP receives the bits of the test data word which has previously been written in, said bits having been latched in the register TR. In response to a comparison command CS, the comparison device provides a test result signal which is representative of the result of the comparison between the 64-bit test data word which has been written and the 64-bit test data word which has been read from the addressed memory bank.

In the simplest case, the test result signal RE may be a binary signal which has a first logic value (for example “1”) with the meaning “error-free” only when all of the bits of the two words which have been compared match. The other logic value (for example “0”) then signals errors. The signal RE can be supplied, via an external connection of the memory module which is used for this purpose, for example via one of the data connections DA (as shown in FIG. 1), to a tester (not shown) which also provides the address information for the successive test write and test read operations. The test result for 64 memory cells is thus “compressed” to 1 bit.

In the ACTM principle described above, the same 4-bit pattern is respectively written to all N/4=16 addressed cell quadruples during a test write operation. This regularity in the 64-bit test data word which has been written greatly differs from practice in the useful mode, which is disadvantageous because the test is not very “realistic”. Another disadvantage is that this test scheme cannot be used to detect the influence of coupling effects (crosstalk) within the buses. The lines of the data bus DB and also the lines of the bank buses BB0 and BB1 are very close to one another in the spaces between the memory banks in order to be able to dimension these spaces such that they are as narrow as possible and thus to make optimum use of the chip area. Even with extremely careful integration technology, production errors or particular circumstances may result in the degree of (capacitive or inductive) coupling between some lines exceeding the permitted extent and thus corrupting the data bits on these lines.

For example, the “low” potential of a line, which represents a data bit with the binary value “0”, can thus be driven up by the “high” potential of adjacent lines, which represent “1” bits, through capacitive coupling to such an extent that the “0” bit is wrongly assessed as a “1” bit. If there is an undesirably high level of coupling between individual lines, this is usually expressed by characteristic patterns, that is to say bits which are assigned to particular lines are corrupted. The known scheme cannot be used to test, for example, interactions between the lines after next. Another problem is caused by undesirable leakage paths between lines at the points at which the bank bus halves cross.

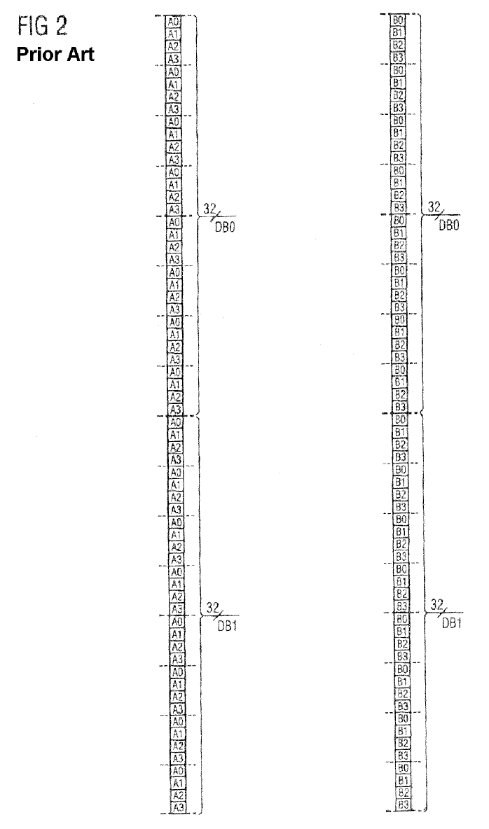

Coupling effects of the type described above could be tested in the most reliable manner by respectively assigning one bit of a first binary value (for example “0”) to only a single one of the N bus lines and assigning bits of the other binary value (that is to say “1”) to all remaining N−1 lines. N successive test cycles with the N possible permutations of this scheme would result in optimum reliability of the test. However, this ideal test cannot be achieved, not even approximately, with the known ACTM scheme, as explained below with reference to FIG. 2.

FIG. 2 shows the possible ways of assigning test data to the N=64 lines of the internal data bus DB and thus to the N=64 lines of the bank bus BB0 or BB1 in the known ACTM scheme. If the changeover switch MX4 in the test auxiliary device TH1 is in the switching state “0”, the assignment of the test data A0:3 shown in the left-hand part of FIG. 2 results. If the changeover switch MX4 is in the “1” state, the assignment of the test data B0:3 shown in the right-hand part results. In both cases, the same 4-bit test data pattern is respectively cyclically repeated over the entire bus width. This scheme does not allow, for example, bits of the second binary value to be assigned to more than three adjacent lines in the immediate vicinity of a line which is carrying a bit of a first binary value.

The bit pattern source could be widened from 4 to N bits in order to provide the N-bit test data word with a pattern which does not have the regularity that exists in the known case, with the result that the test simulates a useful mode in an improved manner. However, this would take up a very large amount of space on the chip area of the memory module.

According to an embodiment of the invention a test auxiliary device in a memory module comprises a multiplicity of memory cells which can be addressed in groups of N respective cells by means of an item of address information in order to selectively read or write N data bits from or to the addressed cell group at the same time using N internal data lines, and a data interface which, in the write mode, converts a data burst comprising P=N/Q successive words of Q respective parallel data bits, which are received at Q data connections, into an N-bit parallel word for application to the N internal data lines, and which, in the read mode, converts an N-bit parallel word, which has been read using the N internal data lines, into a burst of P successive words of Q respective parallel data bits for application to the Q data connections. Provided in the test auxiliary device is a test pattern selection device for choosing between at least two elementary test patterns of M respective test data bits, which have been provided, and for applying the chosen test data bits to the N internal data lines, N/M being an integer >1. The test pattern selection device contains an adjustable allocation device in order to allocate a test pattern, which can be individually chosen from the R>2 elementary M-bit test patterns provided, to each of the N/M disjunct groups of M respective directly adjacent data lines.

The test auxiliary device according to the embodiments invention may manage with a few different elementary and relatively small M-bit test patterns in order to simulate an use mode. The amount of space required for register cells for providing the elementary test patterns can thus be kept small. Two elementary M-bit test patterns each having M=4 test data bits may generally suffice to introduce irregularity into the N test data bits, which considerably increases the likelihood of detecting coupling effects which cause errors.

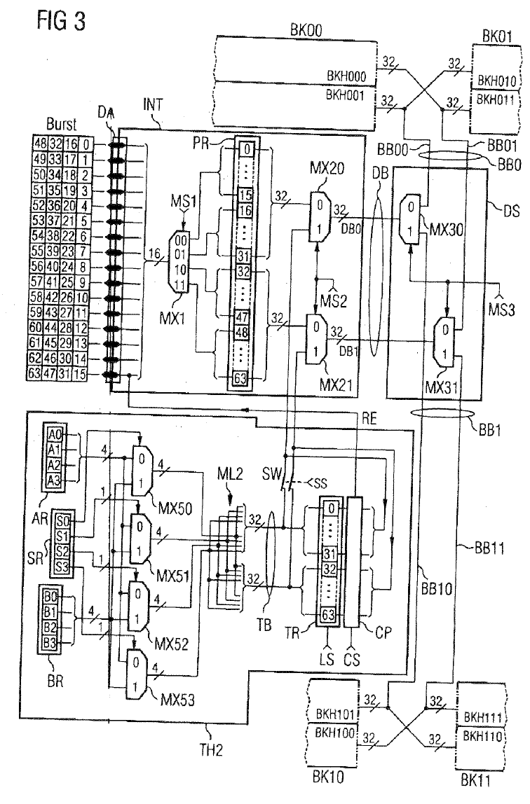

FIG. 3 shows the same memory module as in FIG. 1 with the only difference that the test auxiliary device TH1 illustrated in FIG. 1 has been replaced with a test auxiliary device TH2 according to an embodiment of the invention. The test auxiliary device TH2 contains a test data bus TB having N=64 parallel lines for transmitting a 64-bit test data word to the internal data bus DB of the memory module. The test auxiliary device TH2 likewise contains two bit pattern sources AR and BR which provide two elementary patterns of M=4 respective parallel test data bits A0:3 and B0:3. However, instead of a single changeover switch, a plurality J of two-way changeover switches MX50:53 are provided in order to distribute the test patterns A0:3 and B0:3 among the N lines of the test data bus TB in a programmable manner. The number J must of course be an integer fraction of N. J is preferably equal to Q/M but this is not absolutely necessary; J=4 in the case shown.

Each of the changeover switches MX50:53 has two M-bit inputs, the first of which receives the M=4 bits of the first test pattern A0:3 and the second of which receives the M=4 bits of the second test pattern B0:3. Each of the changeover switches MX50:53 can be set using a bit (which is individually assigned to it) of a control word comprising J=4 bits S0:3 in order to transmit either the first or the second test pattern to its M-bit output. The control word S0:3 is stored in a control register SR and its bit pattern can be set as desired before each test write operation.

In a branching device ML2, each of the M-bit outputs of the changeover switches MX50:53 is branched J times, to be precise is branched to J=4 groups of M respective output lines, thus resulting in a total of N=64 output lines which form the 64-bit test data bus TB. That is to say the M-bit output of each of the changeover switches MX50:53 respectively serves one group of M directly adjacent lines in each of the J disjunct blocks or “strands” of N/J=16 respective directly adjacent lines of the test data bus TB and thus of the internal data bus DB as well. It is thus possible to generate any desired combination of the two elementary test data patterns A0:3 and B0:3 in the individual line strands, this combination being determined by the bit pattern S0:3 of the control register SR and being the same in all J line strands.

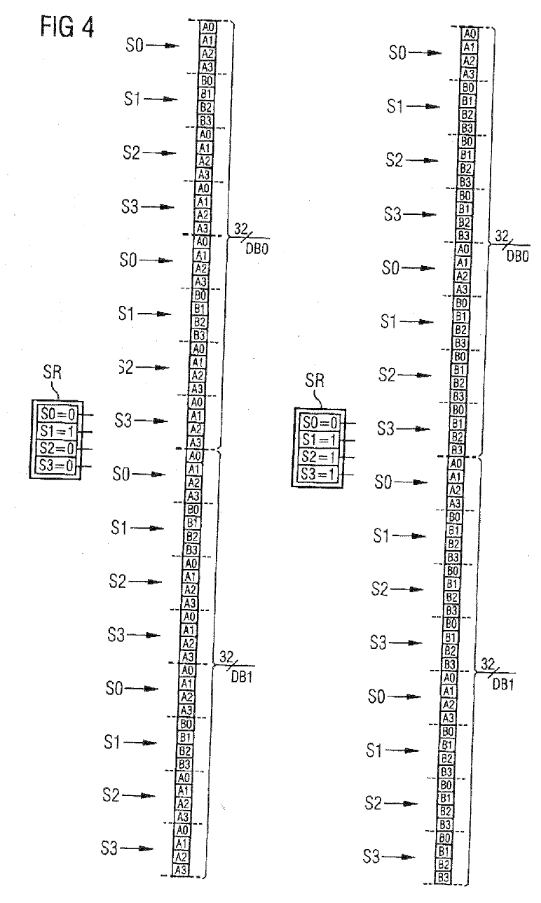

The left-hand side of FIG. 4 shows the test pattern distribution among the 64 parallel bus lines when S0=“0”, S1=“1”, S2=“0” and S3=“0”, that is to say when the control word comprising the control bits S0:3 has the pattern “0100”. The boundaries of the groups of M=4 respective lines which carry an M-bit test data pattern are indicated using thin dashed lines. The boundaries of the J line strands defined above are indicated using thick dashed lines. On account of the fact that S0=“0”, the changeover switch MX50 is in the “0” state, with the result that the first group of four lines in each strand carries the test pattern A0:3. On account of the fact that S1=“1”, the changeover switch MX51 is in the “1” state, with the result that the second group of four lines in each strand carries the test pattern B0:3. On account of the fact that S2=“0”, the changeover switch MX52 is in the “0” state, with the result that the third group of four lines in each strand carries the test pattern A0:3. On account of the fact that S3=“0”, the changeover switch MX53 is in the “0” state, with the result that the fourth group of four lines in each strand also carries the test pattern A0:3.

The right-hand side of FIG. 4 illustrates the test pattern distribution among the 64 bus lines for the example in which the control pattern S0:3 is equal to “0111”.

It can be seen that many different test pattern distributions among the N=64 bus lines are possible with the test auxiliary device TH2 shown in FIG. 2, that is to say there is a great level of flexibility as regards the test options. If, for example, the bit combination “1111” is chosen for the second elementary test pattern B0:3 and a bit combination which contains only a single “0” and otherwise nothing but “1” bits is chosen for the first elementary test pattern A0:3 and the control word S0:3, a bit pattern in which each “0” bit has fifteen adjacent “1” bits is produced on the 64 bus lines, which, although it does not correspond to the ideal case mentioned above, comes considerably closer to this ideal than is possible with the known scheme. Shifting the “0” bit of the first test pattern and shifting the “1” bit of the control word makes it possible, in this manner, to test all 64 bus lines in 16 steps.

In the test auxiliary device TH2 shown in FIG. 3, a 64-bit test data word is written from the test data bus TB to 64 selected memory cells in an addressed bank, and a test data word which has been read out is compared with the word which has been written, using the switch SW, the test data register TR and the comparator CP in the same manner as described with reference to FIG. 1. The test pattern sources AR and BR can be implemented using registers whose cells can be loaded with any desired bit patterns.

Since, in the embodiment shown in FIG. 3, the number J of changeover switches and thus also the number of line strands are equal to Q/M, each line strand comprises Q lines which, in the useful mode, each carry a Q-bit parallel word, the PxQ data burst which is carried via the external data connections DA being composed of said parallel words.

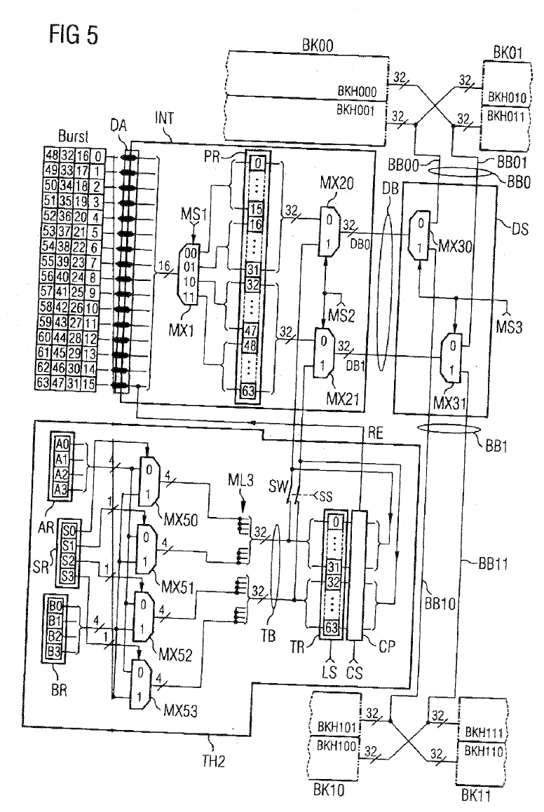

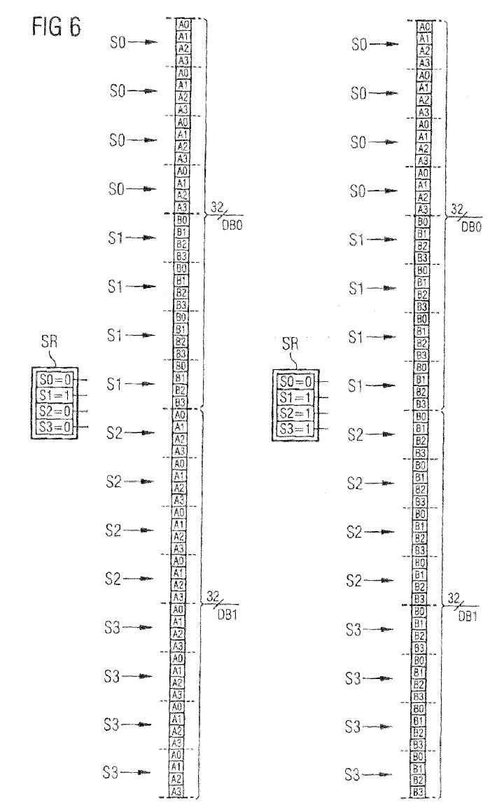

A further embodiment of the invention is described below with reference to FIGS. 5 and 6. FIG. 5 shows the same memory module as in FIG. 1 with the only difference that the test auxiliary device TH1 illustrated in FIG. 1 has been replaced with another test auxiliary device TH3 according to the invention. Like the test auxiliary device TH2 which was described with reference to FIG. 3, the test auxiliary device TH3 contains a test data bus TB having N=64 parallel lines for transmitting a 64-bit test data word to the internal data bus DB of the memory module. The test auxiliary device TH3 likewise contains two bit pattern sources AR and BR which provide two elementary patterns of M=4 respective parallel test data bits A0:3 and B0:3. A number K of two-way changeover switches MX50:53 are provided as the selection device in order to distribute the test patterns A0:3 and B0:3 among the 64 lines of the test data bus TB in a programmable manner. The number K must of course be an integer fraction of N. K is preferably equal to P, that is to say equal to the number of successive Q-bit parallel words which the data burst, which is carried via the external data connections DA, comprises in the useful mode. K=4 in the case shown.

Each of the changeover switches MX50:53 in FIG. 5 has two 4-bit inputs, the first of which receives the 4 bits of the first test pattern A0:3 and the second of which receives the 4 bits of the second test pattern B0:3. Each of the changeover switches MX50:53 can be set using a bit (which is individually assigned to it) of a control word comprising K=4 bits S0:3 in order to transmit either the first or the second test pattern to its 4-bit output. The control word S0:3 is stored in a control register SR and its bit pattern can be set as desired before each test write operation.

A branching device ML3 is used to connect each of the M-bit outputs of the changeover switches MX50:53 to N/(K*M)=4 associated and directly adjacent groups of M=4 respective lines of the test data bus TB in a parallel manner. A strand of N/K=16 directly adjacent bus lines is thus assigned to each of the changeover switches MX50:53. The overall pattern of the test data bits provided on the N=64 bus lines is shown in FIG. 6 for two different bit combinations of the control word S0:3.

The left-hand side of FIG. 6 shows the test pattern distribution among the 64-bit bus when S0=“0”, S1=“1”, S2=“0” and S3=“0”, that is to say when the control word comprising the control bits S0:3 has the pattern “0100”. In this case too, the boundaries of the groups of M=4 respective lines which carry an M-bit test data pattern are indicated using thin dashed lines. The boundaries of the K line strands defined above are indicated using thick dashed lines. On account of the fact that S0=“0”, S2=0, S3=0, the changeover switches MX50, MX52, MX53 are in the “0” state, with the result that the respective N/K lines of the first, third and fourth strands respectively carry the first test data pattern A0:3 in cyclical order. On account of the fact that S1=“1”, the changeover switch MX51 is in the “1” state, with the result that the Q lines of the second strand carry the second test data pattern B0:3 in cyclical order. The right-hand side of FIG. 6 illustrates the test pattern distribution for the case in which the control pattern S0:3 is equal to “0111”.

A 64-bit test data word is written from the test data bus TB to 64 selected memory cells in an addressed bank, and a test data word which has been read out is compared with the word which has been written, using the switch SW, the test data register TR and the comparator CP in the same manner as described with reference to FIG. 1 and also FIG. 3. The test pattern sources AR and BR can be implemented using registers whose cells can be loaded with any desired bit patterns.

Since, in the embodiment shown in FIG. 5, the number K of changeover switches and thus also the number of line strands are equal to P, each line strand comprises, in this case too, Q lines which each carry a Q-bit parallel word in the useful mode, the PxQ data burst which is carried via the external data connections DA being composed of said parallel words.

The test auxiliary devices TH2 and TH3 shown in FIGS. 3 and 5 are only examples. Other modifications and other variants for implementing the invention are also possible, some of which are described briefly below:

The separate N-bit register TR in the test auxiliary device TH2 or TH3 can be omitted and the prefetch register PR contained in the interface INT can be used instead to hold the N-bit test data word, which is generated and written in the test mode, for subsequent comparison with the N-bit word which is read out. To this end, a suitable changeover device which, in the test mode, connects the test data bus TB of the test auxiliary device TH2 to the N signal connections of the register TR could be provided between the changeover switch MX1 and the prefetch register PR.

The comparison device CP may also be designed in such a manner that, rather than comparing the test data bits which have been read with those which have been written in an overall manner for the entire N-bit test data word, it compares them according to specified discrete groups of test data bits. The test result then comprises a plurality of bits, each of which indicates the integrity of the group of bits in question or that the latter contains errors. This allows more accurate conclusions to be drawn regarding the possible locations or causes of any errors.

In order to save test time, all memory banks may be addressed simultaneously in the test write mode in order to respectively write the same N-bit test data word to N addressed memory cells in each bank. To this end, the test auxiliary device may contain suitable switching means (not shown) in order to simultaneously connect the N lines of the internal data bus to the two bank buses BB0 and BB1.

More than two test pattern sources AR and BR may also be provided in order to be able to generate an N-bit pattern in the test mode, in which the individual M-bit groups or the individual Q strands can change between more than two possible patterns. If there are R>2 test pattern sources, corresponding R-way changeover switches need to be provided in the test auxiliary device TH2 or TH3 instead of the two-way changeover switches MX50:53, and the control signal source SR needs to be correspondingly modified in order to generate four parallel control signals, each of which has R possible variations for setting the associated changeover switch.

The test auxiliary device described with reference to FIGS. 3 and 5 in connection with a memory module in which two memory banks respectively share a common N-bit bank bus. However, this configuration (known as “Shared Data Lines”) which has the advantage of requiring a small amount of space between the banks is not necessary for implementing the invention. It goes without saying that the test auxiliary device according to the embodiments of the invention functions just as well in a memory module in which a separate N-bit bank bus, which can be selectively connected to the internal N-bit data bus DB using a data path switching device which is controlled by the bank address, is provided for each bank. In this case, it is not necessary to divide the internal data bus DB and also the test data bus TB into two halves, with the result that the two 32-bit changeover switches MX20 and MX21 can be replaced with a single 64-bit changeover switch and the two 32-bit two-way changeover switches MX30 and MX31 in the data path switching device DS have to be replaced with a 64-bit four-way changeover switch.

It shall also be mentioned that the numerical specifications N=64 and Q=16 are only examples of the internal and external parallelism. The invention functions in memory modules having any desired internal and external parallelism and is expedient whenever P=N/Q>2. This applies to DDR memory modules (double data rate, P=2) as well as to DDR2 modules (quadruple data rate, P=4), DDR3 modules (octuple data rate, P=8) and of course also modules having data rates of an even higher order. The numbers N and Q (and thus also P) are advantageously integer powers of 2, Q being an integer multiple of 4.

The numerical value M=4 is not compulsory either. However, a condition in any case is for the quotient N/M to be an integer. The quotient Q/M should also advantageously (but not necessarily) be an integer, as required in the exemplary embodiments described. The number M is preferably equal to the number Y of memory cells in the smallest jointly addressable subset or group of memory cells, and Y=4 in currently customary DRAM configurations. However, DRAM configurations in which Y has a value other than 4 but preferably has a value equal to an integer power of 2 are also known or conceivable. If M=Y, each of the disjunct groups of M respective adjacent data lines is preferably connected in order to transmit M data bits from and to one of the N/Y subsets of memory cells.

The preceding description describes advantageous exemplary embodiments of the invention. The features disclosed therein and the claims and the drawings can, therefore, be useful for realizing the invention in its various embodiments, both individually and in any combination. While the foregoing is directed to embodiments of the present invention, other and further embodiments of this invention may be devised without departing from the basic scope of the invention, the scope of the present invention being determined by the claims that follow.

What is claimed is:

1. A test auxiliary device for a memory module, comprising:
a test pattern selection device containing an allocation device applying a test pattern to a group of M data lines of the memory module, M being an integer;
wherein the applied test pattern is selected from at least 2 elementary M-bit test patterns.

2. The test auxiliary device as claimed in claim 1, wherein M is at least 4.

3. The test auxiliary device as claimed in claim 1, wherein the allocation device contains a number of changeover switches.

4. The test auxiliary device as claimed in claim 3, wherein the allocation device contains a control register having a number of storage locations corresponding to the number of changeover switches.

5. A memory module, comprising:
a multiplicity of memory cells addressable in groups of N respective cells by means of an item of address information to selectively read or write N data bits from or to the addressed cell group using N data lines, N being an integer; and
a test auxiliary device containing an adjustable allocation device which applies a test pattern to each of the N/M non-adjacent groups of M data lines, N/M being an integer >1; wherein the applied test pattern is selected from R elementary M-bit test patterns, where R is an integer greater than one.

6. The memory module device as claimed in claim 5, wherein M is at least 4.

7. The memory module as claimed in claim 5, wherein the allocation device contains a number of changeover switches.

8. The memory module as claimed in claim 7, wherein the allocation device contains a control register having a number of storage locations corresponding to the number of changeover switches.

9. The memory module as claimed in claim 5, further comprising:
a data interface which, in the write mode, converts a data burst comprising P=N/Q successive words of Q respective parallel data bits, which are received at Q data connections, into an N-bit parallel word for application to the N data lines, and which, in the read mode, converts an N-bit parallel word, which has been read using the N data lines, into a burst of P successive words of Q respective parallel data bits for application to the Q data connections.

10. The memory module as claimed in claim 5, wherein the test pattern selection device selects the test pattern from between at least two elementary test patterns of M respective test data bits, and applies the selected test pattern to the N internal data lines, N/M being an integer >1.

11. An apparatus, comprising:
a memory module comprising a multiplicity of memory cells addressable in groups of N respective cells by means of an item of address information in order to selectively read or write N data bits from or to the addressed cell group at the same time using N internal data lines;
a data interface which, in the write mode, converts a data burst comprising P=N/Q successive words of Q respective parallel data bits, which are received at Q data connections, into an N-bit parallel word for application to the N internal data lines, and which, in the read mode, converts an N-bit parallel word, which has been read using the N internal data lines, into a burst of P successive words of Q respective parallel data bits for application to the Q data connections,
a test pattern selection device configured to apply test bits of a selected test pattern to the N internal data lines; wherein the test pattern is selected from R elementary M-bit test patterns and is applied to each of N/M groups of M respective directly adjacent data lines, where N/M and R are integers greater than one.

12. The apparatus as claimed in claim 11, wherein
a test pattern selection device contains a number J of changeover switches, each of which is assigned to a respective group of M directly adjacent data lines in each of the total of J strands of Q respective directly adjacent data lines and can be changed over between R switching states using an individually assigned item of control information in order to respectively allocate the test pattern, selected from the R elementary test patterns, to each group of N/J respective directly adjacent data lines within a strand.

13. The apparatus as claimed in claim 12, wherein
J is equal to Q/M.

14. The apparatus as claimed in claim 11, wherein
a test pattern selection device contains a number K of changeover switches, each of which is assigned to one of K non-adjacent strands of N/K respective directly adjacent data lines and can be changed over between R switching states using an individually assigned item of control information in order to apply the selected elementary test pattern to all N/(K*M) non-adjacent groups of data lines in the relevant strand.

15. The apparatus as claimed in claim 14, wherein
K is equal to P.

16. The apparatus as claimed in claim 12, wherein
a test pattern selection device further comprises a control register having a number of storage locations corresponding to the number of changeover switches, each of which is individually assigned to one of the changeover switches, and any desired item of control information of R different items of control information being able to be loaded into each of said storage locations in order to determine the switching state of the assigned changeover switch.

17. The apparatus as claimed in claim 11 in which a smallest selectable subset of memory cells comprises Y respective directly adjacent memory cells, wherein
M is equal to Y,
and wherein each of the non-adjacent groups of M respective adjacent data lines is connected in order to transmit the M data bits from and to one of the N/Y subsets of memory cells.

18. The apparatus as claimed in claim 17, wherein M=Y is an integer power of 2.

19. The apparatus as claimed in claim 18, wherein M=Y=4.

20. The apparatus as claimed claim 11, wherein R is equal to 2.

21. A method of selecting a test pattern for a memory module, comprising:
selecting a test pattern from at least 2 elementary M-bit test patterns; and
applying the selected test pattern to a group of M data lines of N internal data lines of the memory module, M being an integer.

22. The method as claimed in claim 21, wherein respective test bits of the selected test pattern are applied to each of the N internal data lines, and wherein applying comprises applying the selected test pattern to each of N/M non-adjacent groups of M respective directly adjacent data lines, where N/M is an integer greater than one.

23. The method as claimed in claim 22, further comprising
addressing, in groups of N, respective cells by means of an item of address information in order to selectively read or write N data bits from or to the addressed cell group at the same time using the N internal data lines;
in the write mode, converting a data burst comprising P=N/Q successive words of Q respective parallel data bits, which are received at Q data connections, into an N-bit parallel word for application to the N internal data lines, and
in the read mode, converting an N-bit parallel word, which has been read using the N internal data lines, into a burst of P successive words of Q respective parallel data bits for application to the Q data connections.

24. The method as claimed in claim 23, in which a smallest selectable subset of memory cells comprises Y respective directly adjacent memory cells, wherein
M is equal to Y,
and wherein each of the non-adjacent groups of M respective adjacent data lines is connected in order to transmit the M data bits from and to one of the N/Y subsets of memory cells.

25. The method as claimed in claim 24, wherein M=Y is an integer power of 2.

26. The method as claimed in claim 25, wherein M=Y=4.
